(19) United States
(12) Patent Application Publication
(10) Pub. No.: US 2025/0206598 A1
(43) Pub. Date: Jun. 26, 2025

(54) APPARATUS FOR STRESS-REDUCED MOUNTING OF MEMS-BASED MICROMIRRORS

(71) Applicant: Carl Zeiss SMT GmbH, Oberkochen (DE)

(72) Inventors: Markus HAUF, Ulm (DE); Stefan WALZ, Schwäbisch Gmünd (DE); Yanko Sarov, Aalen (DE); Fabian Haacker, Aalen (DE)

(21) Appl. No.: 19/078,330

(22) Filed: Mar. 13, 2025

Related U.S. Application Data
(63) Continuation of application No. PCT/EP2023/075291, filed on Sep. 14, 2023.

(30) Foreign Application Priority Data
Sep. 21, 2022 (DE) 102022209935.4

(51) Int. Cl. B81B 7/00; G03F 7/00

(52) U.S. Cl. CPC B81B 7/0029; G03F 7/70175; B81B 2201/042

(57) ABSTRACT

An apparatus for stress-reduced mounting of MEMS-based micromirrors on a metallic support structure comprises a plate extending in a main plane of extent and a plurality of compensation elements which are connected to the plate and have connecting elements which extend across the main plane of extent and a plurality of base elements. A respective group with a plurality of connecting elements is connected to a common base element. The apparatus is produced using MEMS technology.

### CROSS-REFERENCE TO RELATED APPLICATIONS

The present application is a continuation of, and claims benefit under 35 USC 120 to, international application No. PCT/EP2023/075291, filed Sep. 14, 2023, which claims benefit under 35 USC 119 of German Application No. 10 2022 209 935.4, filed Sep. 21, 2022. The entire disclosure of each of these applications is incorporated by reference herein.

### FIELD

The disclosure relates to an apparatus for stress-reduced mounting of MEMS-based micromirrors on a metallic support structure. The disclosure also relates to an optical component and an optical assembly. Further, the disclosure relates to a method for producing an apparatus for stress-reduced mounting of micromirrors. In this context, stress relates to mechanical stresses.

### BACKGROUND

The use of micromirror arrays in illumination optical units for projection exposure apparatuses is known.

It can be challenging to ensure precise and stable positioning of displaceable mirrors, even in the case of a high thermal load.

In general, it is desirable to improve optical components and assemblies with micromirrors, especially with regards to the mounting of such micromirrors.

### SUMMARY

In an aspect, the disclosure provides an apparatus having a plurality of compensation elements for compensating different lateral thermal expansions of a support structure and the micromirrors arranged thereon, for the purpose of mounting micromirrors, such as MEMS-based micromirrors.

The compensation elements can have a high stiffness and/or a thermal conductivity that is as high as possible in a first direction for example, the latter, without loss of generality, also being referred to as vertical direction hereinafter. In at least one direction running across the latter, which is also referred to as a lateral direction, the compensation elements can be designed to be resilient.

In the vertical direction for example, the compensation elements may have a stiffness which is greater than a stiffness in at least one direction perpendicular thereto, for example greater by at least a factor of 5, for example greater by at least a factor of 10, and for example greater by at least a factor of 20.

In general, the compensation elements may be designed so that the vertical stiffness and/or the vertical thermal conductivity is kept close to the optimum, for example of a completely unstructured layer, while their lateral stiffness is reduced, especially to keep shear and peel stresses small.

The lateral stiffness of the compensation elements may for example be reduced by approximately one order of magnitude, for example vis-à-vis the shear stiffness of a homogeneous, which is to say non-structured, layer of the same height.

Laterally, the stiffness of the compensation elements may be direction dependent. For example, it may be greater in a first direction across the vertical direction, for example perpendicular to the vertical direction, than in a second direction perpendicular thereto, for example greater by at least a factor of 5, for example greater by at least a factor of 10 and for example greater by at least a factor of 20.

A compensation of different lateral thermal expansions, especially at the transition from silicon to metal, can be achieved as a result. For example, this can achieve a reduction of mechanical stresses, for example shear and/or peel stresses, which are also referred to as stress hereinafter. At the same time, it is possible to ensure great stability in the orientation of a plate which serves as a reference surface and extends in a main plane of extent.

For example, the apparatus can be produced via MEMS technology, for example via silicon technology. In particular, this should be understood to mean that the apparatus is produced via structuring and bonding methods, for example only comprising structuring steps, such as lithographic structuring steps, and/or bonding steps.

In this context, a MEMS (microelectromechanical system) denotes an electromechanical component made of a semiconductor, for example silicon, germanium or selenium, or a semiconductor compound.

Hereinafter, MEMS technology denotes methods and process technology for processing and shaping such materials. Hereinafter, MEMS technology should be understood to mean lithographic structuring methods and/or laser ablation methods for example.

For example, the micromirrors are MEMS-based micromirrors. This should be understood to mean that the micromirrors are produced from one of the aforementioned materials, for example silicon or a silicon compound.

For example, the compensation elements have planar, leaf-shaped or pin-shaped structures.

These may be connected to a plate. They may extend across the main plane of extent of the plate, for example parallel to a surface normal of a surface of the plate. Without loss of generality, the surface normal of the plate is also referred to as the vertical direction hereinafter.

The plate is also referred to as an interposer plate. For example, the whole apparatus for stress-reduced mounting of the optical components is referred to as an interposer.

For example, the interposer forms an intermediate layer between the silicon-based components, for example a chip stack, and a metallic support. For example, the arrangement of a chip stack, for example having a plurality of semiconductor chips and/or MEMS components arranged above or on one another, on a metallic support is improved, for example made possible, via the interposer.

The structures of the compensation elements may have different cross sections.

The structures may have an elongate cross section, for example in the direction parallel to the main plane of extent.

For example, the structures may have greater resilience in a first direction across the vertical direction than in a second direction, perpendicular to the first direction, across the vertical direction. The ratio of the lateral resilience values in two directions parallel to the main plane of extent can be at least 2:1, for example at least 3:1, for example at least 5:1, for example at least 10:1, for example at least 20:1, for example at least 30:1, for example at least 50:1, and for example at least 100:1.

The structures may also be pin-shaped and have a round, such as circular, and/or quadrilateral, for example rectangular, such as square, cross section.

A combination of different compensation structures is likewise possible.

In general, the compensation structures are referred to as connecting elements hereinafter.

They are mechanically connected to the plate. For example, they may be formed in one piece with the plate. A corresponding production is possible via MEMS technology. The use of MEMS technology enables the production of very fine structures. This makes it possible to keep the length of the connecting elements short in the vertical direction and simultaneously ensure a sufficient lateral resilience, at least in a specified direction. Reducing the height of the connecting elements in the vertical direction may be desirable in relation to a reduction of a thermal resistance of these elements. Moreover, this may reduce the absolute longitudinal thermal expansion of the connecting elements. This can help yield greater stability and precision of the micromirror mount.

At their end distant from the plate, the connecting elements are connected to a base element. For example, they may be formed in one piece with the base element.

For example, provision can be made for a respective group with a plurality of connecting elements to be connected to a common base element. The base element is also referred to hereinafter as a foot.

For example, the base element serves as an element of the apparatus for mounting the micromirrors, which provides contact with a support structure that is also referred to as a base plate. For example, the support structure may be made of metal and/or comprise metallic regions.

What can be achieved by combining a plurality of connecting elements into groups and connecting the latter to a common base element is that each group independently forms a parallel guide along a resilient direction. This can significantly reduce the influx of bending moments into the joining points of the base element and the support structure.

The base element may comprise one or more planar structures.

The base element may comprise one or more joints, for example one or more tilting joints, for example flexures, for example tilting joints which are based not on friction but on material bending. In this case, at least one of the joints may be connected to the planar structure, which is connected to the support structure via a joining point. For example, the joint can be arranged on or at the planar structure. It may be formed in one piece with the planar structure.

Decoupling of moments may be enabled and/or improved via the joint or joints. For example, the joints lead to a reduction in the influx of bending moments into the joining points between the base element and the substrate on which the base element is arranged.

The joints may each have one or more degrees of tilting freedom.

A tilting joint may be arranged for example between two of the planar structures of the base element.

A joint, for example a tilting joint, may be arranged between one or more compensation elements and the aforementioned plate of the mounting apparatus.

The connecting elements may also have thickenings, for example central thickenings, especially in an embodiment with a joint, for example in an embodiment with a plurality of joints. The bending behaviour of the connecting elements can be influenced with the aid of such thickenings. Thickenings may also lead to a reduction in the thermal resistance of the connecting elements.

The base element may in each case be connected to the support structure by extensive bond connections, for example adhesive bonding, eutectic bonding, diffusion bonding, welding bonding or soldering bonding. Alternative connections, for example mechanical connections, for example an interlocking accommodation of the base element in the support structure, are likewise possible.

For example, the apparatus can help make it possible to ensure that heat from the micromirrors is dissipated well to the support structure. The latter, for example its plate, forms a mechanically stable, planar reference surface for the arrangement of the micromirrors. This can help make it possible to ensure that no thermal deformations which can have a disadvantageous influence on the positioning, for example on the tilt position of the micromirrors, arise, or at least that any such thermal deformations are only minor. It also can help make it possible to ensure that the reference pressure between a vacuum region and a normal pressure region on opposite sides of the plate is absorbed without deformations or leaks. Finally, the apparatus can help make it possible to realize electrical connections between the vacuum-side MEMS components and the normal pressure-side supply electronics.

The apparatus is also referred to as an interposer or MEMS interposer.

The connecting elements are also referred to as decoupling elements or stress decoupling elements.

For example at least 50%, for example at least 75%, for example at least 90%, for example at least 95% and for example all, of the apparatus may be produced from, for example consist of, a semiconductor material, for example silicon, germanium or selenium, or an appropriate semiconductor compound.

Such materials can help allow the compensation elements to be produced in very fine, precise and reproducible fashion using precisely controllable process technology, for example via MEMS technology.

According to an aspect, the connecting elements each have an aspect ratio of height, for example in the vertical direction, to effective thickness, for example in a direction perpendicular to the vertical direction, of at least 5:1, for example of at least 10:1, for example of at least 15:1 and for example of at least 20:1. It was possible to show that this allows the global shear stress to be reduced significantly.

In particular, the effective thickness here refers to the thickness of the connecting elements that is relevant to their pliability. For example, the minimal thickness of the connecting elements may be referred to as effective thickness.

In the case of an aspect ratio of 20:1, the stress dominated in the bonding sites in the case of the exemplary embodiments examined.

For example, the aspect ratio of the connecting elements may be no more than 50:1, for example no more than 30:1, and for example no more than 20:1.

According to an aspect, the connecting elements may have a height in the vertical direction ranging from 100 μm to 3 mm, for example in the range of less than 1 mm and for example of no more than 500 μm.

According to an aspect, the connecting elements may have an effective thickness in a direction perpendicular to the vertical direction of no more than 300 μm, for example no more than 200 μm, for example no more than 100 μm, for example no more than 50 μm and for example no more than 25 μm.

The connecting elements may have a planar embodiment according to an aspect. For example, they may be in the form of leaf springs. The connecting elements of a group may each be aligned parallel with one another or concentric to one another. For example, they may have a common, matching alignment with a common centre, for example with a centre of a thermal expansion. As a result, it is possible to obtain isotropic thermal expansion in relation to the thermal centre with very little thermal warping.

The connecting elements of the same group may for example each be aligned perpendicular to a common surface normal or, in the case of a curved embodiment, have the same radial direction.

Connecting elements of different groups may have different orientations.

For example, provision can be made for the alignment of the connecting elements to be chosen on the basis of their arrangement in the radial direction relative to a respective centre of a thermal expansion. In this case, connecting elements in the same radial direction may be aligned parallel with one another or concentric to one another. Connecting elements in different radial directions may have different orientations/radial directions.

According to an aspect, through silicon vias (TSVs) may be provided in the plate for the purpose of transmitting control signals and/or supply voltages. For example, supply voltages and/or control signals can be guided via the TSVs to ASICs, for example front-end ASICs and/or controller ASICs, for controlling the displacement of the micromirrors. Copper vias in silicon may also be provided in place of or in addition to through silicon vias.

For example, the TSVs may be arranged in one or more rows. This can keep the width of the apparatus which is to be bridged by the plate and not supported by connecting elements small.

The TSVs may also be arranged in any other pattern, for example a regular pattern. By way of example, a region with compensation structures may be arranged in each case between two TSVs.

According to an aspect, the plate may comprise one or more electrically conductive layers or conductor tracks and/or passive components, for example decoupling capacitors for supply voltages, and/or active components, for example voltage regulators. Combinations of such elements are also possible. For example, these elements may be arranged on the side of the plate opposite to the connecting elements.

In general, the apparatus may have one or more electrically functional layers or structures extending in the direction of the main plane of extent. This, too, is made possible by the production via MEMS technology.

An optical component comprises a micromirror array having a plurality of micromirrors, for example MEMS-based micromirrors, and an apparatus according to the description above.

The features are evident from those of the apparatus.

The micromirror array may comprise micromirrors, chips, ASICs and other MEMS structures/elements. The electronic components, for example chips and/or ASICs, and other MEMS structures may be arranged between the micromirrors and the planar silicon support of the interposer, for example.

These elements may form a MEMS stack, for example. The individual elements of the MEMS stack may be connected to one another via bonding structures, for example bonding pads. In this case, the bonding pads may establish a mechanical and/or electrical and/or thermal connection between the ASIC chips and the MEMS chip. Regarding details of the MEMS stack, reference should be made to DE 10 2022 204663.3, the entirety of which is hereby incorporated into the present application.

The micromirror array, the ASIC chips and the interposer can be connected to one another and/or to further components, for example in punctiform or extensive fashion. For example, connections are possible by way of Si—Si direct bonding, adhesive bonding, eutectic bonding (e.g., Au—Si, Al—Si or Au—Ge) and Cu/dielectric hybrid bonding connections (e.g., Cu—SiO2 hybrid bonding or Cu/adhesive hybrid bonding). Moreover, Cu—Cu bonding with or without solders and via Sn micro-bumps is also possible.

The vias of the chips may be implemented as TSVs. This allows a laterally gap-free structure which in turn is desirable for a gap-free arrangement of the micromirrors that is as tight as possible.

For example, the optical component can serve as a facet mirror, for example as a field facet mirror or as a pupil facet mirror, or as a specular reflector of an illumination optical unit in a projection exposure apparatus.

Other applications, for example using micromirrors, are also possible, for example wavefront manipulation/correction mirrors, which operate by way of adjustments of the individual mirrors in the Z-direction.

An optical assembly comprises a support structure for holding optical components, at least one apparatus according to the description above and at least one micromirror array having a plurality of micromirrors, for example MEMS-based micromirrors.

The features are evident from those already described.

The support structure may be metallic, at least in part and for example in full. For example, it may be made, at least in part and for example in full, from a material having a thermal conductivity of at least 100 W/(m*K), for example at least 200 W/(m*K), and for example at least 300 W/(m*K). For example, it can be made, at least in part and for example in full, from aluminium, copper or a copper-containing compound, for example CuBe or CuZn.

The assembly may serve as a facet mirror, for example as a field facet mirror, pupil facet mirror or as a specular reflector.

The micromirror arrays may have modular embodiments. This makes it possible to arrange, for example exchange, the micromirror arrays independently of one another on the support structure.

According to an aspect, the connecting elements of the apparatus for mounting the micromirrors are connected directly or indirectly to the support structure via bonding structures.

According to an aspect, the support structure may have vacuum bushings for leading contact elements through in vacuum-tight fashion, for the purpose of electrically contacting the apparatus.

The support structure can thus form a boundary between a vacuum region and a normal pressure region.

For example, the contact elements may have a pin-shaped design, for example be embodied as contact pins.

According to an aspect, elastically designed and/or elastically mounted contact elements can be arranged at least in certain regions in the support structure, for the purpose of contacting the apparatus. For example, the contact elements can be designed to be laterally resilient. For example, the contact elements can be the aforementioned contact pins.

The elastic and/or resilient design and/or mount of the contact elements can enable particularly reliable contacting of the apparatus.

The contact elements, for example contact pins, may be designed to be elastic over their entire length. They may also contain only partial regions or portions that are elastic and otherwise have a rigid, such as inelastic embodiment. For example, they may have one, two, three or more defined kinking or bending points.

When the apparatus is arranged on the support structure, the contact elements may come to rest on predetermined pads of the apparatus for example. On account of the elastic design and/or mount of the contact elements, the pads themselves need not have an elastic embodiment. They may be securely connected to the decoupling apparatus and/or arranged on the latter.

The elastic embodiment and/or arrangement of the contact elements allows the establishment of a largely constant contact force, and hence a reliable electrical connection, by pressing the contact elements against the pads of the decoupling apparatus.

According to an aspect, contact elements, such as contact pins, which are arranged in one or more rows may be provided for the purpose of contacting the apparatus.

The contacting fields with the contact pins located therebelow may ideally be arranged such that—where possible—only small regions arise which are not supported by connecting elements and hence are to be bridged by the interposer plate. On the one hand, this may be achieved by virtue of the pins being arranged in rows. In this case, only bridging the short direction perpendicular to the row is involved. On the other hand, the pins could be arranged in open two-dimensional contact fields, in which the individual contact fields are surrounded by fields with connecting elements and hence the lengths to be bridged are kept as short as possible in both lateral directions.

For example, the arrangement of the contact pins may correspond precisely to the arrangement of the TSVs, or a selection of the latter.

According to an aspect, the support structure comprises a mechanism for decoupling mechanical stress. For example, decoupling cuts may serve as a mechanism for decoupling mechanical stress. For example, the decoupling cuts may be aligned parallel to the vertical direction.

The mechanism for decoupling mechanical stress may each be arranged adjacent to a base element of the apparatus for mounting the micromirrors. They may be respectively arranged on both sides of such a base element or circumferentially around such a base element.

For example, the mechanism for decoupling mechanical stress may be arranged in each case between two such base elements.

According to an aspect, the support structure may have receptacles for accommodating supply and/or control electronics and/or a cooling structure.

A method for producing an apparatus according to the description above includes, for example, producing compensation elements, for example the connecting elements, via MEMS technology.

This can help make it possible to produce the compensation elements, for example the connecting elements, very precisely and with fine structuring.

Subjects of the disclosure also relate to an illumination optical unit for a projection exposure apparatus, an illumination system, an optical system for a projection exposure apparatus, a projection exposure apparatus, a method for producing a micro- or nanostructured component, and a component produced in accordance with the method.

The features are evident from those already described.

### BRIEF DESCRIPTION OF THE DRAWINGS

Further features and details of the disclosure will become apparent from the description of exemplary embodiments with reference to the figures, in which:

FIG. 1 schematically shows certain constituent parts of a projection exposure apparatus in a meridional section,

FIGS. 2 and 3 schematically show a view of a displaceable mirror element which for example forms a constituent part of a mirror array of a facet mirror for an illumination optical unit of a projection exposure apparatus,

FIG. 4 schematically shows a cross section through a portion of a micromirror array,

FIG. 5 schematically shows a view of an arrangement of a micromirror array on a support structure, with an interposer arranged between the micromirror array and the support structure,

FIGS. 6A and 6B schematically show details of a compensation device for reducing mechanical stresses in the micromirror array, which may arise on account of different coefficients of thermal expansion of the support structure and micromirror array,

FIG. 7 shows an alternative view of the arrangement according to FIG. 5,

FIG. 8 schematically shows a cross section through the arrangement according to FIG. 5,

FIG. 9 schematically shows a cross section through a compensation apparatus,

FIG. 10 shows a schematic illustration for explaining the alignment of the compensation elements with respect to a centre of the thermal expansion according to FIG. 9,

FIGS. 11A to 11D show exemplary graphs which indicate how the shear stress in the substrate and at the joining points can be reduced with the aid of the decoupling apparatus according to the disclosure,

FIGS. 12 and 13 show exemplary graphs which make clear how a surface slope variation (FIG. 12) or a surface deformation (FIG. 13) of the plate of the decoupling apparatus, which serves as a reference surface, can be reduced with the aid of the decoupling elements,

FIGS. 14A and 14B schematically show details of a further variant of a compensation device for reducing mechanical stresses in the micromirror array, which may arise on account of different coefficients of thermal expansion of the support structure and micromirror array,

FIGS. 15A and 15B schematically show details of a further variant of a compensation device for reducing mechanical stresses in the micromirror array, which may arise on account of different coefficients of thermal expansion of the support structure and micromirror array,

FIG. 16 shows a partial view of an arrangement according to FIG. 5, with some constituent parts having been omitted or depicted only in part in order to render underlying structures more visible,

FIG. 17 shows a horizontal section through an arrangement according to FIG. 5, in which the contacts are arranged in a single row,

FIG. 18 shows a view according to FIG. 17 of a variant in which the contacts are arranged in three rows,

FIG. 19 shows a view according to FIG. 17 of a variant in which the contacts are arranged in 2×2 patterns with 3×3 partial patterns, and

FIG. 20 shows a schematic view according to FIG. 5 of a variant with laterally resilient contact pins.

### DETAILED DESCRIPTION

Firstly, the general construction of a projection exposure apparatus 1 and certain constituent parts thereof will be described. For details in this regard, reference should be made to WO 2010/049076 A2, which is hereby fully incorporated in the present application as part thereof. The description of the general structure of the projection exposure apparatus 1 should only be understood to be exemplary. It serves to explain a possible application of the subject matter of the present disclosure. The subject matter of the present disclosure can also be used in other optical systems, for example in alternative variants of projection exposure apparatuses. For example, the interposer concept described hereinafter is not restricted to the structure of the projection exposure apparatus 1, depicted in exemplary fashion, or the constituent parts thereof. For example, its application is not restricted to the specific MEMS design presented in exemplary fashion in this context.

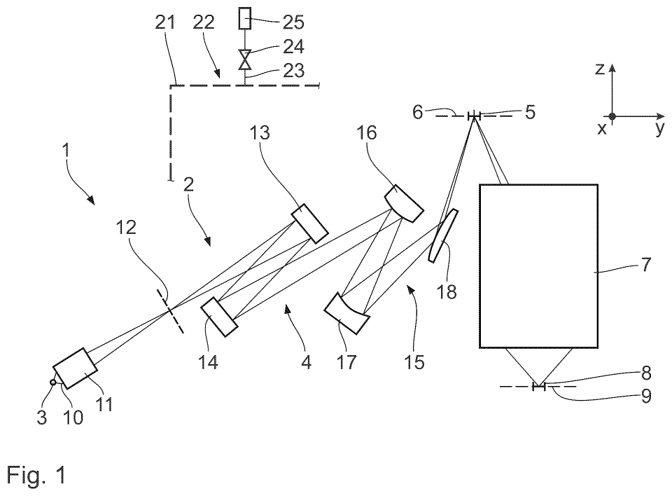

FIG. 1 schematically shows a microlithographic projection exposure apparatus 1 in a meridional section. An illumination system 2 of the projection exposure apparatus 1 has, besides a radiation source 3, an illumination optical unit 4 for the exposure of an object field 5 in an object plane 6. The object field 5 can have a rectangular or arcuate design with an x/y aspect ratio of 13/1, for example. In this case, a reflective reticle (not depicted in FIG. 1) arranged in the object field 5 is exposed, the reticle bearing a structure to be projected by the projection exposure apparatus 1 for the production of micro- or nanostructured semiconductor components. A projection optical unit 7 serves for imaging the object field 5 into an image field 8 in an image plane 9. The structure on the reticle is imaged onto a light-sensitive layer of a wafer, which is not depicted in the drawing and is arranged in the region of the image field 8 in the image plane 9.

The reticle, which is held by a reticle holder (not depicted here), and the wafer, which is held by a wafer holder (not depicted here), are scanned synchronously in the y-direction during the operation of the projection exposure apparatus 1. Depending on the imaging scale of the projection optical unit 7, it is also possible for the reticle to be scanned in the opposite direction relative to the wafer.

The radiation source 3 is an EUV radiation source with emitted used radiation in the range of between 5 nm and 30 nm. This can be a plasma source, for example a GDPP (Gas Discharge Produced Plasma) source or an LPP (Laser Produced Plasma) source. Other EUV radiation sources, for example those based on a synchrotron or on a free electron laser (FEL), are also possible.

EUV radiation 10 emerging from the radiation source 3 is focused by a collector 11. A corresponding collector is known for example from EP 1 225 481 A2. Downstream of the collector 11, the EUV radiation 10 propagates through an intermediate focal plane 12 before being incident on a field facet mirror 13. The field facet mirror 13 is arranged in a plane of the illumination optical unit 4 which is optically conjugate to the object plane 6. The field facet mirror 13 may be arranged at a distance from a plane which is conjugate to the object plane 6. In this case, it is generally referred to as a first facet mirror.

The EUV radiation 10 is also referred to hereinafter as used radiation, illumination radiation or imaging light.

Downstream of the field facet mirror 13, the EUV radiation 10 is reflected by a pupil facet mirror 14. The pupil facet mirror 14 lies either in the entrance pupil plane of the projection optical unit 7 or in a plane optically conjugate thereto. It may also be arranged at a distance from such a plane.

The field facet mirror 13 and the pupil facet mirror 14 are constructed from a multiplicity of individual mirrors, which will still be described in detail below. In this case, the subdivision of the field facet mirror 13 into individual mirrors can be such that each of the field facets illuminating the entire object field 5 by themselves is represented by exactly one of the individual mirrors. Alternatively, it is possible to construct at least some or all of the field facets using a plurality of such individual mirrors. The same correspondingly applies to the configuration of the pupil facets of the pupil facet mirror 14, which are respectively assigned to the field facets and each of which can be formed by a single individual mirror or by a plurality of such individual mirrors.

The EUV radiation 10 is incident on both facet mirrors 13, 14 at a defined angle of incidence. For example, the two facet mirrors are exposed to EUV radiation 10 in the range associated with normal incidence operation, which is to say with an angle of incidence that is less than or equal to 25° in relation to the mirror normal. Exposure to grazing incidence is also possible. The pupil facet mirror 14 is arranged in a plane of the illumination optical unit 4 which constitutes a pupil plane of the projection optical unit 7 or is optically conjugate to a pupil plane of the projection optical unit 7. With the aid of the pupil facet mirror 14 and—optionally—an imaging optical assembly in the form of a transfer optical unit 15 which has mirrors 16, 17 and 18 designated in the order of the beam path for the EUV radiation 10, the field facets of the field facet mirror 13 are imaged into the object field 5 in a manner superimposed on one another. The last mirror 18 of the transfer optical unit 15 is a mirror for grazing incidence (“grazing incidence mirror”). The transfer optical unit 15 together with the pupil facet mirror 14 is also referred to as a sequential optical unit for transferring the EUV radiation 10 from the field facet mirror 13 toward the object field 5. The illumination light 10 is guided from the radiation source 3 toward the object field 5 via a plurality of illumination channels. Each of these illumination channels is assigned a field facet of the field facet mirror 13 and a pupil facet of the pupil facet mirror 14, the pupil facet being disposed downstream of the field facet. The individual mirrors of the field facet mirror 13 and of the pupil facet mirror 14 can be tiltable by an actuator system, such that a change in the assignment of the pupil facets to the field facets and correspondingly a modified configuration of the illumination channels can be achieved. This results in different illumination settings, which differ in the distribution of the illumination angles of the illumination light 10 over the object field 5.

In order to facilitate the explanation of positional relationships, a global Cartesian xyz-coordinate system, inter alia, is used hereinafter. The x-axis runs perpendicular to the plane of the drawing toward the observer in FIG. 1. The y-axis in FIG. 1 runs towards the right. The z-axis runs upwardly in FIG. 1.

Different illumination settings can be achieved by tilting the individual mirrors of the field facet mirror 13 and correspondingly modifying the assignment of the individual mirrors of the field facet mirror 13 to the individual mirrors of the pupil facet mirror 14. Depending on the tilt of the individual mirrors of the field facet mirror 13, the individual mirrors of the pupil facet mirror 14 that are newly assigned to the individual mirrors are updated by tilting such that imaging the field facets of the field facet mirror 13 into the object field 5 is once again ensured.

Further aspects of the illumination optical unit 4 are described below.

The one field facet mirror 13 in the form of a multi- or micro-mirror array (MMA) forms an example of an optical assembly for guiding the used radiation 10, which is to say the EUV radiation beam. The field facet mirror 13 is embodied as a microelectromechanical system (MEMS). It has a multiplicity of individual mirrors 20 arranged in a mirror array 19 in a matrix-like manner in rows and columns. The mirror arrays 19 have a modular embodiment. They can be arranged on a support structure that is embodied as a base plate. Here, it is possible to arrange substantially any number of the mirror arrays 19 next to one another. Consequently, the overall reflection surface which is formed by the totality of all mirror arrays 19, for example by the individual mirrors 20 thereof, is extendable as desired. For example, the mirror arrays are embodied in such a way that they enable a substantially gap-free tessellation of a plane. The ratio of the sum of the reflection surfaces 26 of the individual mirrors 20 to the overall area that is covered by mirror arrays 19 is also referred to as integration density. For example, this integration density is at least 0.5, such as at least 0.6, for example at least 0.7, for example at least 0.8 and for example at least 0.9.

The mirror arrays 19 can be fixed to a base plate, for example via fixing elements 29. For details, reference is made to WO 2012/130768 A2, for example.

The individual mirrors 20 are designed to be tiltable by way of an actuator. For details, reference is made to WO 2012/130 768 A2, for example. Overall, the field facet mirror 13 contains approximately 100 000 of the individual mirrors 20. The field facet mirror 13 may also have a different number of individual mirrors 20 depending on the size of the individual mirrors 20. The number of individual mirrors 20 of the field facet mirror 13 is for example at least 1000, such as at least 5000 and for example at least 10,000. It can be up to 100,000, for example up to 300,000, for example up to 500,000 and for example up to 1,000,000.

A spectral filter can be arranged upstream of the field facet mirror 13 and separates the used radiation 10 from other wavelength components of the emission of the radiation source 3 that are not usable for the projection exposure. The spectral filter is not depicted here.

The field facet mirror 13 is exposed to used radiation 10 with a power of for example 840 W and a power density of 6.5 kW/m2.

The entire individual mirror array of the facet mirror 13 has, for example, a diameter of 500 mm and is designed to be closely packed with the individual mirrors 20. Insofar as a field facet is realized by exactly one individual mirror in each case, the individual mirrors 20 represent the shape of the object field 5, apart from a scaling factor. The facet mirror 13 can be formed by 500 individual mirrors 20 which each represent a field facet and have a dimension of approximately 5 mm in the y-direction and 100 mm in the x-direction. As an alternative to the realization of each field facet by exactly one individual mirror 20, each of the field facets can be approximated by groups of smaller individual mirrors 20, for example micromirrors. A field facet having dimensions of 5 mm in the y-direction and of 100 mm in the x-direction can be constructed for example via a 1×20 array of individual mirrors 20 with dimensions of 5 mm×5 mm, through to a 10×200 array of individual mirrors 20 with dimensions of 0.5 mm×0.5 mm.

The tilt angles of the individual mirrors 20 are adjusted for the purpose of changing the illumination settings. For example, the tilt angles have a displacement range of +50 mrad, for example ±100 mrad. An accuracy of better than 0.2 mrad, for example better than 0.1 mrad, is achieved within the scope of setting the tilt position of the individual mirrors 20.

The individual mirrors 20 of the field facet mirror 13 and of the pupil facet mirror 14 in the embodiment of the illumination optical unit 4 according to FIG. 1 bear multilayer coatings for the purpose of optimizing their reflectivity at the wavelength of the used radiation 10. The temperature of the multilayer coatings should not exceed 425 K during the operation of the projection exposure apparatus 1. This is achieved by a suitable structure of the individual mirrors 20. For details, reference is made to DE 10 2013 206 529 A1, which is hereby fully incorporated into the present application.

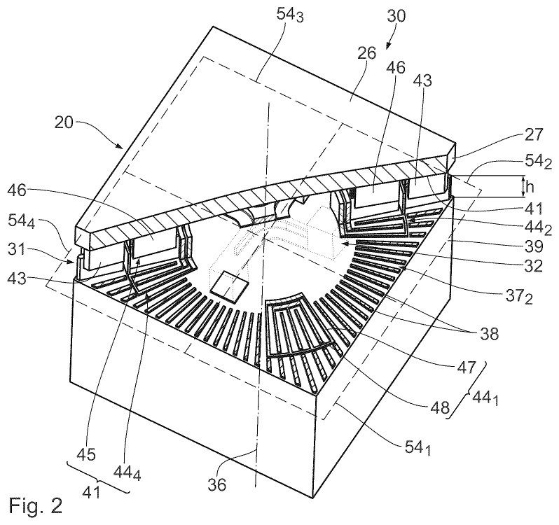

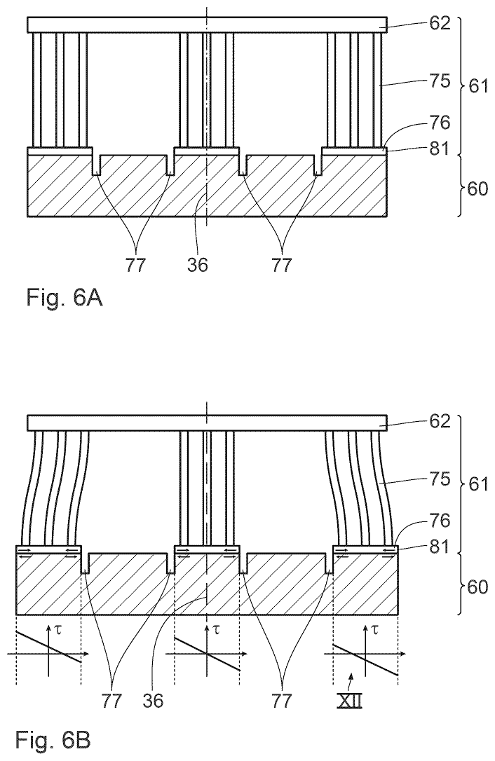

The individual mirrors 20 of the illumination optical unit 4 are accommodated in an evacuable chamber 21, a boundary wall 22 of which is indicated in FIGS. 2 and 6. The chamber 21 communicates with a vacuum pump 25 via a fluid line 23, in which a shut-off valve 24 is accommodated. The operating pressure in the evacuable chamber 21 is a few pascals, for example 3 Pa to 5 Pa (partial pressure H2). All other partial pressures are significantly below 1× 10-7 mbar.

Together with the evacuable chamber 21, the mirror comprising the plurality of individual mirrors 20 forms an optical assembly for guiding and/or shaping a beam of the EUV radiation 10.

Each of the individual mirrors 20 can have a reflection surface 26 with dimensions of 0.1 mm×0.1 mm, 0.5 mm×0.5 mm, 0.6 mm×0.6 mm, or else of up to 5 mm×5 mm or larger. The reflection surface 26 can also have smaller dimensions. For example, it has side lengths in the μm range or low mm range. The individual mirrors 20 are therefore also referred to as micromirrors.

The reflection surface 26 is part of a mirror body 27 of the individual mirror 20. The mirror body 27 carries the multilayer coating. The mirror body 27 may for example be produced from, for example consist of, a semiconductor material, for example silicon, or a semiconductor compound, for example a silicon compound.

For the lithographic production of a micro- or nanostructured component, for example a semiconductor component, for example a microchip, at least one part of the reticle is imaged onto a region of a light-sensitive layer on the wafer with the aid of the projection exposure apparatus 1. Depending on the embodiment of the projection exposure apparatus 1 as a scanner or as a stepper, the reticle and the wafer are moved in the y-direction in a manner synchronized in time, continuously in scanner operation or step by step in stepper operation.

Further details and aspects of the mirror array 19, for example of the optical components which comprise the individual mirrors 20, are described below.

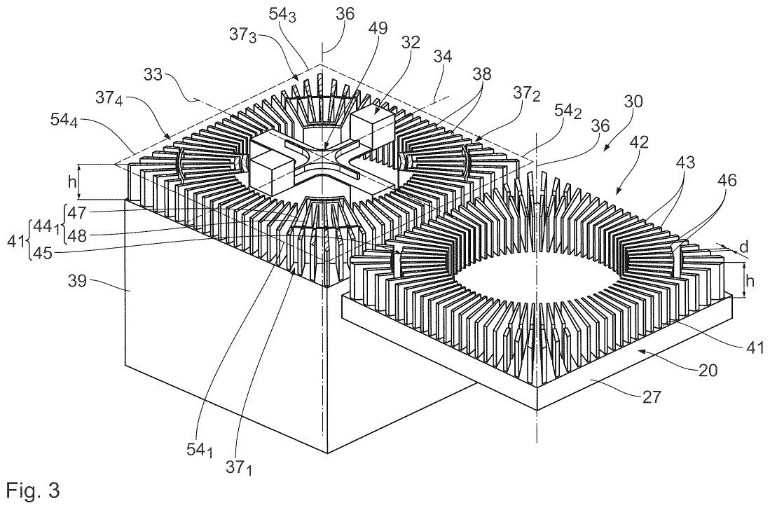

Initially, a first variant of an optical component 30 comprising an individual mirror 20 and for example the displacement device 31 for displacing, for example for pivoting, the individual mirror 20 is described in exemplary fashion with reference to FIGS. 2 and 3. These details should be understood to be exemplary and, for example, non-restrictive. Alternative embodiments of the component 30 are known and likewise possible.

The illustration according to FIG. 3 corresponds to that according to FIG. 2, with the mirror body 27 of the individual mirror 20 being folded away to the side in FIG. 3. As a result, the structures of the displacement device 31 and of the sensor device 41 are better visible.

The optical component comprises the individual mirror 20 which, for example, is embodied as a micromirror. The individual mirror 20 comprises the mirror body 27 described above, on the front side of which the reflection surface 26 is formed. For example, the reflection surface 26 is formed by a multilayer structure. For example, the radiation of the illumination radiation 10, for example of the EUV radiation, is reflected thereby.

The reflection surface 26 is square according to the variant depicted in the figures; however, it has been drawn in partly sectioned fashion in order also to show the actuator system. It generally has a rectangular embodiment. It may also have a triangular or hexagonal embodiment. For example, it has a tile-like embodiment such that a gap-free tessellation of a plane by way of the individual mirrors 20 is possible.

The individual mirror 20 is mounted via a joint 32. For example, it is mounted in such a way that it has two degrees of freedom of tilting. For example, the joint 32 allows the individual mirror 20 to be tilted about two tilt axes 33, 34. The tilt axes 33, 34 are perpendicular to one another. They intersect at a central point of intersection, which is referred to as the effective pivot point.

To the extent that the individual mirror 20 is in a non-pivoted neutral position, the effective pivot point lies on a surface normal 36 which runs through a central point, for example the geometric centroid of the reflection surface 26.

To the extent that nothing else is specified, the direction of the surface normal 36 hereinafter is always understood to mean the direction of same in the non-tilted neutral position of the individual mirror 20.

Firstly, the displacement device 31 is described in detail below.

The displacement device 31 comprises an electrode structure comprising actuator transducer stator electrodes 37ᵢ and actuator transducer mirror electrodes 42. According to the variant depicted in FIGS. 2 and 3, the electrode structure comprises four actuator transducer stator electrodes 37₁, 37₂, 37₃ and 37₄. In general, the number of actuator transducer stator electrodes 37ᵢ is at least 2. It may be 3, 4 or more.

All actuator transducer electrodes 37i, 42 are embodied as comb electrodes comprising a plurality of comb fingers 38. The respectively complementary comb fingers of the mirror and stator engage in one another in this case. The combs of the individual actuator electrodes 37i in each case comprise 30 actuator transducer stator comb fingers 38, which are also referred to as stator comb fingers or merely comb fingers for short hereinafter. A different number in each case is likewise possible. The number of the comb fingers 38 of the actuator transducer stator electrodes 37ᵢ is for example at least 2, for example at least 3, for example at least 5 and for example at least 10. It may be up to 50 and for example up to 100.

The combs of the actuator transducer mirror electrodes 42 accordingly comprise actuator transducer mirror comb fingers 43, which are also referred to as mirror comb fingers or merely comb fingers for short hereinafter. The number of the mirror comb fingers 43 corresponds to the number of the stator comb fingers. It may also deviate from the number of stator comb fingers by one in each case.

The comb fingers 38 are arranged in such a way that they extend in the radial direction in relation to the surface normal 36 or the effective pivot point. According to a variant not depicted in the figures, the comb fingers 38, 43 may also be arranged tangentially to circles around the effective pivot point. They may also have an embodiment which corresponds to sections of concentric circular cylinder lateral surfaces around the surface normal 36.

All of the actuator transducer stator electrodes 37ᵢ are arranged on a substrate 39. For example, they are fixedly arranged on the substrate 39. For example, they are arranged in a single plane that is defined by the front side of the substrate 39. This plane is also referred to as the actuator plane 40 or as comb plane.

For example, a wafer serves as a substrate 39. The substrate 39 is also referred to as the mirror base plate.

The actuator transducer stator electrodes 37ᵢ are each arranged in a region on the substrate 39 which, firstly, has a square outer contour and, secondly, a circular inner contour. As an alternative thereto, the actuator transducer stator electrodes 37ᵢ may also be arranged in an annular region on the substrate 39. Here, the outer contour also has a circular embodiment. For example, the individual actuator transducer stator electrodes 37ᵢ are respectively arranged in annular-segment-shaped regions. The electrode structure overall, which is to say all of the actuator transducer stator electrodes 37ᵢ, is arranged in a region which has an outer contour that, to all intents and purposes, corresponds to that of the reflection surface of the individual mirror 20. It may also be arranged in a slightly smaller region, for example a region that is smaller by approximately 5% to 25%.

The electrode structure has a radial symmetry. For example, it has a fourfold radial symmetry. The electrode structure may also have a different radial symmetry. For example, it may have a threefold radial symmetry. For example, it has a k-fold radial symmetry, where k specifies the number of actuator transducer stator electrodes 37ᵢ. Apart from the subdivision of the electrode structure into the different actuator transducer stator electrodes 37ᵢ, the electrode structure has an n-fold radial symmetry, where n, to all intents and purposes, corresponds to the overall number of comb fingers 38 of all actuator transducer stator electrodes 37ᵢ.

Apart from their different arrangement on the substrate 39, the individual actuator transducer stator electrodes 37ᵢ have the same embodiment. This is not mandatory. They may also have different embodiments. For example, their embodiment may depend on the mechanical properties of the joint 32.

The comb fingers 38 are arranged radially in relation to the effective pivot point, or radially in relation to the alignment of the surface normal 36 in the non-pivoted neutral state of the individual mirror 20.

In the case of individual mirrors 20, the mirror bodies 27 of which have dimensions of 1 mm. 1 mm, the comb fingers 38 have a thickness d of no more than 5 μm at their radially outer end. In general, the maximum thickness d of the comb fingers 38 at their radially outer end lies in the range of 1 μm to 20 μm, for example in the range of 3 μm to 10 μm.

The comb fingers 38 have a height h, which is to say an extent in the direction of the surface normal 36, in the range of 10 μm to 100 μm, for example in the range of 20 μm to 50 μm. Other values are likewise conceivable. The height h is constant in the radial direction. It may also decrease in the radial direction. This can enable larger tilt angles, without leading to the comb fingers of the actuator mirror electrode 42 being incident on the mirror base plate.

Adjacent comb fingers 38, 43 of the actuator electrodes 37ᵢ on the one hand and of the actuator mirror electrodes 42 on the other hand have a minimum spacing in the range of 1 μm to 10 μm, for example in the range of 3 μm to 7 μm, for example approximately 5 μm, in the non-pivoted state of the individual mirror 20. These values can be scaled appropriately for individual mirrors 20 with smaller or larger dimensions.

This minimum spacing m is the minimum distance between adjacent mirror comb fingers and stator comb fingers, measured in the neutral, non-pivoted state of the individual mirror 20. The comb fingers may approach one another when the individual mirror 20 is tilted. The minimum spacing m is selected in such a way that there is no collision between adjacent mirror comb fingers and stator comb fingers, even in the case of the maximum tilt of the individual mirror 20. Here, manufacturing tolerances are taken into account. Such manufacturing tolerances are a few micrometres, for example at most 3 μm, for example at most 2 μm and for example at most 1 μm.

The closest possible approach of adjacent comb fingers 38, 43 can easily be determined from the geometric details of same and the arrangement thereof, and the maximum possible tilt of the individual mirror 20. In the present embodiment, the closest approach of adjacent comb fingers 38, 43 is approximately 2 μm in the case of a tilt of the individual mirror 20 through 100 mrad. For example, the closest approach is less than 10 μm, for example less than 7 μm, for example less than 5 μm and for example less than 3 μm.

The actuator transducer stator electrodes 37ᵢ each interact with an actuator mirror electrode 42. The actuator mirror electrode 42 is connected to the mirror body 27. For example, the actuator mirror electrode 42 is mechanically securely connected to the mirror body 27. The actuator transducer mirror electrodes 42 form a counter electrode to the actuator transducer stator electrodes 37ᵢ. Therefore, they are also simply referred to as the counter electrode.

The actuator mirror electrode 42 forms a passive electrode structure. This should be understood to mean that the actuator mirror electrode 42 has a fixed, constant voltage applied thereto.

The actuator mirror electrode 42 has a complementary embodiment to the actuator transducer stator electrodes 37ᵢ. For example, it forms a ring with actuator transducer mirror comb fingers 43, which, for simplification purposes, are also referred to as mirror comb fingers or only as comb fingers 43 hereinafter. In terms of their geometric properties, the mirror comb fingers 43 of the actuator mirror electrode 42 substantially correspond to the stator comb fingers 38 of the actuator transducer stator electrodes 37ᵢ.

All comb fingers 38, 43 may have the same height h, which is to say identical dimensions in the direction of the surface normal 36. This simplifies the production process.

In the direction of the surface normal 36, the mirror comb fingers 43 of the actuator mirror electrode 42 may also have a different height to that of the stator comb fingers 38 of the active actuator transducer stator electrodes 37ᵢ.

The comb fingers 38, 43 may have a height h that decreases in the radial direction. It is also possible to design the comb fingers 38, 43 in the region of the corners of the optical component 30 to be shorter than the remaining comb fingers 38, 43. This can allow a greater tilt angle of the individual mirror 20.

For example, the actuator mirror electrode 42 is embodied in such a way that one respective comb finger 43 of the actuator mirror electrode 42 is able to be immersed in an interstice between two of the comb fingers 38 of the actuator transducer stator electrodes 37ᵢ.

The actuator mirror electrode 42 is electrically conductively connected to the mirror body 27. Therefore, their comb fingers 43 are equipotential. The mirror body 27 has a low resistance connection to the mirror base plate by way of an electrically conductive joint spring. In principle, it is also possible to electrically connect the mirror substrate, which is to say the mirror body 27, the actuator mirror electrodes 42 and the sensor mirror electrodes 45, via the flexure 32 on an individual basis by way of separate supply lines and thus, for example, put these at different potentials or decouple these in respect of faults and/or crosstalk. The mirror base plate may be earthed, but this need not be the case. Alternatively, it is possible that the mirror can be kept at a different potential and be connected to a voltage source by way of conductive joint springs, but be electrically isolated from the mirror plate. As a result of this, it is possible to apply a fixed or variable bias voltage to the mirror.

An actuator voltage UA can be applied to the actuator transducer stator electrodes 37ᵢ for the purpose of pivoting the individual mirror 20. Therefore, the actuator transducer stator electrodes 37ᵢ are also referred to as active actuator transducer stator electrodes 37ᵢ. A voltage source that is not depicted in the figures is provided for applying the actuator voltage UA to the actuator transducer stator electrodes 37ᵢ. The actuator voltage UA can be up to 200 volts or more. It is at least 100 volts. By suitably applying the actuator voltage UA to a selection of the actuator transducer stator electrodes 37ᵢ, the individual mirror 20 can be tilted through up to 50 mrad, for example up to 100 mrad, for example up to 150 mrad, from a neutral position. Alternatively, the actuators can also be actuated by a source of charge (source of current).

Different actuator voltages U_{Ai} can be applied to the various actuator transducer stator electrodes 37ᵢ for the purpose of pivoting the individual mirror 20. A control device that is not depicted in the figures is provided for controlling the actuator voltages U_{Ai}.

For the purpose of tilting one of the individual mirrors 20, an actuator voltage UA is applied to one of the actuator transducer stator electrodes 37ᵢ. At the same time, an actuator voltage U_{A2}≠U_{A1} deviating therefrom is applied to the actuator transducer stator electrode 37ᵢ that lies opposite thereto in relation to the surface normal 36. Here, U_{A2}=0 volts is possible. For example, it is possible to apply the actuator voltage U_{A1} to only one of the actuator transducer stator electrodes 37ᵢ, while all other actuator transducer stator electrodes 37j are kept at a voltage of 0 volts.

When the individual mirror 20 is tilted, the comb fingers of the actuator mirror electrode 42 are immersed more deeply between the comb fingers 38 of the actuator transducer stator electrode 37ᵢ on one side, for example in the region of this actuator transducer stator electrode 37ᵢ to which the actuator voltage UA has been applied. On the opposite side of the tilt axis 33, the actuator mirror electrode 42 is immersed less deeply into the actuator transducer stator electrodes 37ⱼ. The actuator mirror electrode 42 may even emerge from the actuator transducer stator electrodes 37ⱼ, at least in certain regions.

The comb overlap, which is to say the immersion depth of the actuator mirror electrode 42 between the actuator transducer stator electrodes 37ᵢ, is 30 μm in the neutral position of the individual mirror 20 in the case of a mirror dimension of approximately 0.5 mm×0.5 mm.

Proceeding from the neutral position, a tilt of the mirror 20 through 100 mrad may lead to a maximum reduction of the distance between the comb fingers 43 of the actuator mirror electrode 42 and the comb fingers 38 of the actuator transducer stator electrodes 37ᵢ by 1.1 μm. Consequently, the comb fingers 43 of the actuator mirror electrode 42 and the comb fingers 38 of the actuator transducer stator electrodes 37ᵢ are spaced apart from one another, for example without contact, in every pivot position of the mirror 20. For example, the immersion depth, which is to say the comb overlap, is selected in such a way that this is ensured.

A sensor device 41 is provided for detecting the pivot position of the individual mirror 20. The sensor device 41 may form a constituent part of the displacement device 31.

The sensor device 41 comprises sensor transducer mirror electrodes 45 and sensor transducer stator electrodes 44ᵢ.

The sensor unit comprises four sensor transducer stator electrodes 44₁ to 44₄. For simplification purposes, the sensor transducer stator electrodes 44ᵢ are also referred to as sensor electrodes only. For the actuation, it is desirable for the number of sensor transducer stator electrodes 44ᵢ to correspond exactly to the number of actuator transducer stator electrodes 37ᵢ. However, the number of sensor transducer stator electrodes 44ᵢ can also deviate from the number of actuator transducer stator electrodes 37ᵢ.

The sensor transducer stator electrodes 44₁ to 44₄ are each arranged along the diagonal of the substrate 39 in the variant according to FIGS. 2 to 5. In the variant depicted in FIGS. 2 to 5, the sensor transducer stator electrodes 44₁ to 44₄ are arranged with a 45° offset relative to the tilt axes 33, 34 of the joint 32.

The actuator transducer stator electrodes 37ᵢ are arranged in quadrants 54₁ to 54₄, respectively, on the substrate 39. The sensor transducer stator electrodes 44ᵢ are each arranged in the same quadrant 54₁ to 54₄ as one of the actuator transducer stator electrodes 37ᵢ in each case. The actuator device 31, for example the arrangement and embodiment of the actuator transducer stator electrodes 37ᵢ, has substantially the same symmetry properties as the reflection surface 26 of the individual mirror 20. The sensor device, for example the sensor transducer stator electrodes 44ᵢ, has substantially the same symmetry properties as the reflection surface 26 of the individual mirror 20.

Two sensor transducer stator electrodes 44ᵢ that lie opposite one another in respect of the effective pivot point are in each case interconnected in a differential manner. However, such an interconnection is not mandatory. In general, it is desirable for two sensor electrodes 44ᵢ that lie opposite one another in respect of the effective pivot point to be in each case embodied and arranged in such a way that they can be read in a differential manner.

The sensor transducer stator electrodes 44ᵢ are embodied as comb electrodes. For example, the sensor transducer stator electrodes 44ᵢ can be embodied in a manner corresponding to the actuator transducer stator electrodes 37ᵢ, with reference herewith being made to the description thereof. The sensor transducer stator electrodes 44ᵢ each comprise a sensor transducer stator transmitter electrode 47, which is also referred to as transmitter electrode for short hereinafter, and a sensor transducer stator receiver electrode 48, which is also referred to as receiver electrode for short hereinafter. Both the sensor transducer stator transmitter electrode 47 and the sensor transducer stator receiver electrode 48 have a comb structure. For example, they comprise a plurality of comb fingers. For example, the comb fingers of the sensor transducer stator transmitter electrode 47 are arranged in alternation with the comb fingers of the sensor transducer stator receiver electrode 48.

The sensor device 41 comprises a sensor transducer mirror electrode 45 for each of the sensor transducer stator electrodes 44ᵢ. According to an embodiment, the sensor transducer mirror electrodes 45 each form a shielding unit of the sensor transducer stator electrodes 44ᵢ. The sensor transducer mirror electrode 45 in each case comprises comb elements with a plurality of comb fingers 46. The sensor transducer mirror electrode 45 is embodied in accordance with a counter electrode in order to match the sensor transducer stator electrodes 44ᵢ. For example, the sensor transducer mirror electrodes 45 can be embodied in a manner corresponding to the actuator transducer mirror electrodes 42, with reference herewith being made to the description thereof.

The sensor transducer mirror electrodes 45 are each securely connected to the mirror body 27. They are arranged in the region of the diagonal of the mirror body 27. When the individual mirror 20 is tilted, the sensor transducer mirror electrode 45 can each be immersed between the comb fingers of the sensor transducer stator electrodes 44ᵢ, for example between the transmitter electrode 47 and the receiver electrode 48, to a different depth. As a result of this, there is a variable shielding of adjacent comb fingers, for example a variable shielding of the receiver electrode 48 from the transmitter electrode 47. This leads to a change in the capacitance between the adjacent comb fingers of the sensor transducer stator electrodes 44ᵢ when the individual mirror 20 is pivoted. This change in capacitance can be measured. To this end, the inputs of a piece of measuring equipment can be connected to the comb fingers of the sensor transducer stator electrodes 44ᵢ in alternation.

The immersion depth of the sensor transducer mirror electrodes 45 between the sensor transducer stator electrodes 44ᵢ, for example between the transmitter electrodes 47 and the receiver electrodes 48, is 30 μm. This ensures that the comb fingers 46 still have a residual immersion depth at each point between the transmitter electrodes 47 and the receiver electrodes 48, even in the maximally tilted pivot position, which is to say they never completely emerge. This ensures the differential sensor operation over the entire tilt range. Then again, the immersion depth of the sensor transducer mirror electrode 45 is selected in such a way that there is no collision of same with the substrate 39, even in the maximally tilted pivot position of the individual mirror 20.

A voltage, for example a sensor voltage Us, is applied to the transmitter electrode 47 for the purpose of measuring the capacitance between the transmitter electrode 47 and the receiver electrode 48 of the sensor transducer stator electrodes 44ᵢ. For example, an AC voltage serves as a sensor voltage Us.

The sensor device 41 is sensitive in view of the immersion depth of the comb fingers 46 between adjacent comb fingers of the sensor transducer stator electrodes 44ᵢ (FIG. 6).

The sensor device 41 is insensitive to pure pivoting of the comb finger 46 relative to the transmitter electrode 47 and the receiver electrode 48.

The sensor device 41 is insensitive to a lateral displacement of the shielding element which changes the distance of same from the transmitter electrode 47 and from the receiver electrode 48 but leaves the immersion depth of the comb finger 46 between the adjacent transmitter and receiver electrodes 47, 48 unchanged.

Reference is made by way of example to WO 2016/146 541 A1 with regards to further details of the sensor device.

The sensor transducer stator electrodes 44ᵢ are arranged within the ring of the actuator transducer stator electrodes 37ᵢ. In this region, the absolute movements of the comb fingers 46 in the direction parallel to the surface normal 36 are smaller than outside of the ring of the actuator transducer stator electrodes 37ᵢ. The absolute scope of movement is related to the distance from the effective pivot point 37.

The sensor transducer stator electrodes 44ᵢ are embodied and arranged radially in relation to the effective pivot point. For example, they have comb fingers that extend in the radial direction. This reduces the sensitivity in relation to a possible thermal expansion of the individual mirror 20.

As already explained above, on account of its structure, the sensor device 41 has, at best, a minimal sensitivity in view of parasitic movements of the individual mirror 20, for example in view of displacements perpendicular to the surface normal 36 and/or rotations about the surface normal 36. On account of the shielding principle of the sensor device, the latter also has, at best, a minimal sensitivity in view of a possible thermal expansion of the individual mirror 20. Moreover, the sensor principle has a minimal sensitivity in view of thermal bending of the mirror.

Two sensor units that lie opposite one another in respect of the effective pivot point, each with a transmitter electrode 47 and a receiver electrode 48, are in each case interconnected in a differential manner or at least readable in a differential manner. This renders it possible to eliminate errors in the measurement of the position of the mirror 20, for example on account of eigenmodes of the individual mirror 20.

The active constituent parts of the sensor device 41 are arranged on the substrate 39. This renders it possible to directly measure the tilt angle of the individual mirror 20 relative to the substrate 39. Moreover, the length of the signal line and/or of the supply lines can be reduced, for example minimized, on account of the arrangement of the transmitter electrodes 47 and the receiver electrodes 48 on the substrate 39. This reduces possible disturbing influences. This ensures constant operating conditions.

The transmitter electrodes 47 are each embodied as an active shielding, for example as a shielding ring, about the receiver electrodes 48. This reduces, for example minimizes, for example prevents capacitive crosstalk between the actuator transducer stator electrodes 37ᵢ and the sensor device 41.

The joint 32 can be embodied as Cardan-type flexure for example.

The joint 32 can be embodied as a torsion spring element structure for example. For example, it may comprise two torsion springs.

The joint 32 is stiff in view of rotations about the surface normal 36. The joint 32 is stiff in view of a linear displacement in the direction of the surface normal 36. In this context, stiff means that the natural frequency of the rotational vibrations about the surface normal 36 and the natural frequency of the vibrations in the direction of the surface normal 36 lie above the actuated modes by more than one frequency decade. The actuated tilt modes of the individual mirror lie, for example, at frequencies below 1 kHz, for example below 600 Hz. The natural frequency of the rotational vibrations about the surface normal 36 lies at more than 10 kHz, for example at more than 30 kHz.

The joint 32 has a known flexibility in view of pivoting about the two tilt axes 33, 34. The stiffness of the joint 32 in view of pivoting about the tilt axes 33, 34 can be influenced by a targeted design of the torsion springs.

The joint 32 including the connecting blocks has a plurality of functions. Firstly: binding the non-actuated degrees of freedom; secondly, transporting heat from the mirror 20 to the mirror base plate 39; and, thirdly, establishing the electrical connection between the mirror 20 and the mirror base plate 39. The purpose of the blocks is primarily to create space for the vertical movement of the joint element. It is self-evident the blocks then also transmit the mechanical, thermal, and electrical functions of the springs.

The torsion springs can be made of a material with a thermal conductivity of at least 50 W/(mK), for example at least 100 W/(mK) and for example at least 140 W/(mK).

The torsion springs may be made of silicon or a silicon compound. The joint 32 can be produced from highly doped monocrystalline silicon. This opens up a process compatibility of the production process with established MEMS manufacturing processes. Moreover, this leads to a desirably high thermal conductivity and a good electric conductivity.

In the case of an absorbed power density of 10 kW/(m2) and mirror dimensions of 600 μm×600 μm, a temperature difference of 11 K emerges between the mirror body 27 and the substrate 39 with the specified values of the dimensions, for example with a thickness of the torsion springs of 4 μm, and the thermal conductivity of the torsion springs.

The torsion springs may also have a lower thickness. Should the torsion springs have a thickness of 2.4 μm, a temperature difference of 37 K emerges between the mirror body 27 and the substrate 39—in the case of otherwise identical parameter values.

What could be achieved by such torsion springs is that the temperature difference between the mirror body 27 and the substrate 39 is less than 50 K, for example less than 40 K, for example less than 30 K and for example less than 20 K.

According to a variant of the joint 32, two pairs of bending springs are provided in place of the torsion springs. The joint 32 also has a great stiffness in the horizontal degrees of freedom in this alternative.

A further variant of the joint 32 is a Cardan-type flexure with orthogonally arranged, horizontal bending springs in the form of leaf springs. Two of the bending springs are in each case connected to one another via a planar structure, which is also referred to as an intermediate plate.

Horizontal leaf springs are desirable from a process point of view. For example, they simplify the production of the joint 32.

Reference is made to WO 2016/146 541 A1 with regards to further details of the joint 32.

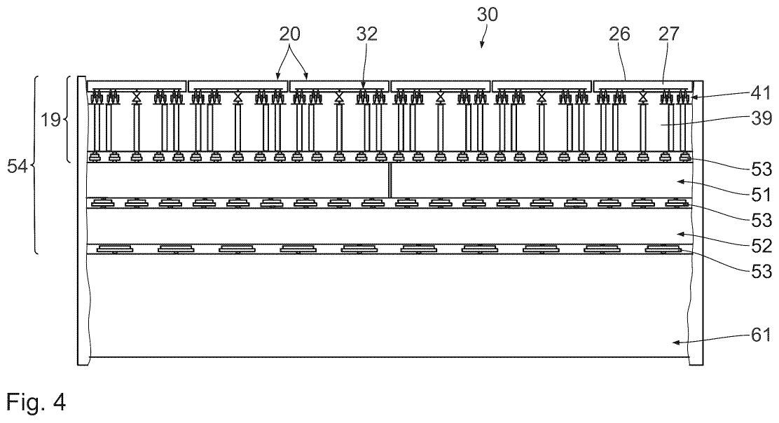

FIG. 4 illustrates a cross section through a portion of the mirror array 19 in the region of one of the individual mirrors 20 in exemplary and schematic fashion. In addition to the mirror array 19 with the individual mirrors 20, which may for example be in the form of MEMS micromirrors, and the substrate 39, which may for example be in the form of a MEMS chip substrate, FIG. 4 schematically illustrates electronic components which may serve for example for control, for example closed-loop control, of the mounting of the individual mirrors 20. Front-end ASICs 51 and controller ASICs 52, for example arranged on the back side of the substrate 39, are depicted.

Bonding pads 53 are also depicted. For example, these may serve the electrical and/or thermal connection between the substrate 39 and the ASICs 51, 52 or further components arranged therebelow, for example a support structure 60 not depicted in FIG. 4.

The controller ASICs 52 and the front-end ASICs 51 may form a stack, for example a MEMS stack 54. The MEMS stack 54 may also comprise the substrate 39. It may also comprise the mirror array 19. Individual elements of the MEMS stack 54 can be connected to one another via the bonding pads 53. In this case, the bonding pads 53 represent the mechanical, electrical and thermal connection between the ASIC chips 51, 52 and the MEMS chip of the mirror array 19.

A via of the chips may be implemented as a TSV (through silicon via). This allows a laterally gap-free structure. The latter is desirable for an arrangement of the individual mirrors 20 which is as tight and gap-free as possible.

FIG. 4 also schematically illustrates an apparatus for stress-reduced mounting of the mirror array 19, for example of the individual mirrors 20, on a support structure 60.

The apparatus for mounting the mirror array 19, for example the individual mirrors 20, yet to be described in detail hereinafter, is also referred to as interposer, intermediate layer or decoupling apparatus 61. The function of mechanically decoupling the components arranged on the opposite sides of the decoupling apparatus 61, for example the MEMS stack 54 and the support structure 60 which may be made of metal for example, is expressed particularly clearly by the designation as a decoupling apparatus 61. The term interposer places more emphasis on the electrical functions of this component.

In principle, the apparatus for stress-reduced mounting of the mirror array 19, for example the individual mirrors 20, may have not only mechanical but also electrical and also thermal functions. In this case, different functions can be arranged over the apparatus in more or less uniformly distributed fashion. They may also be combined in specifically delimited regions. Individual exemplary variants will still be described in detail hereinafter.

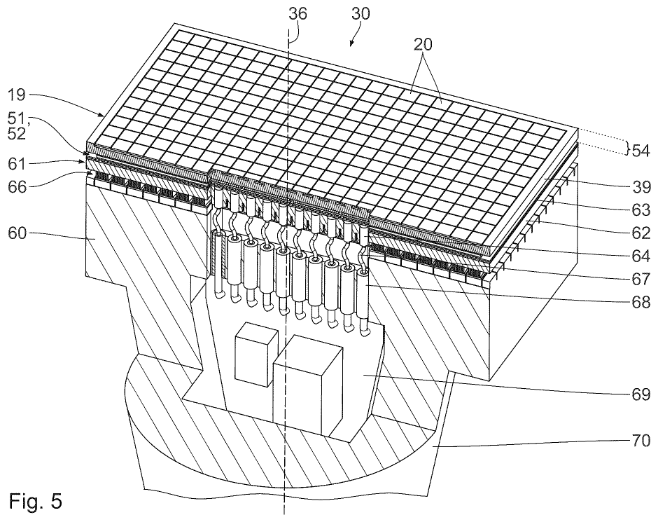

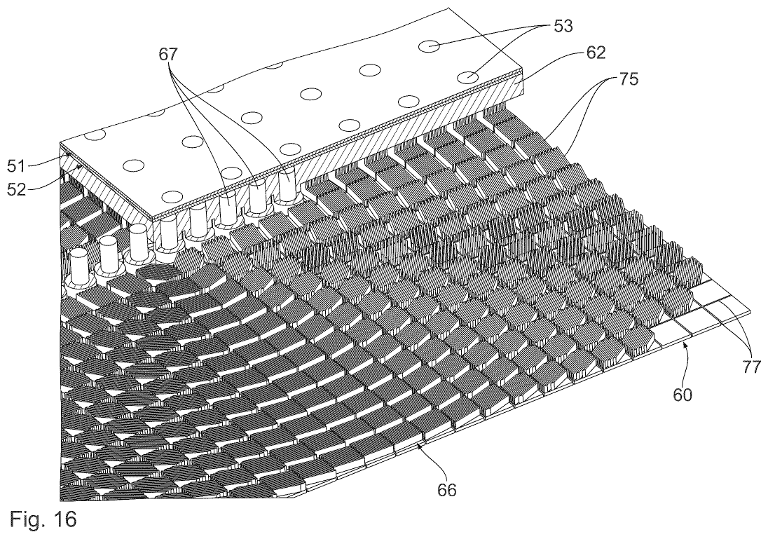

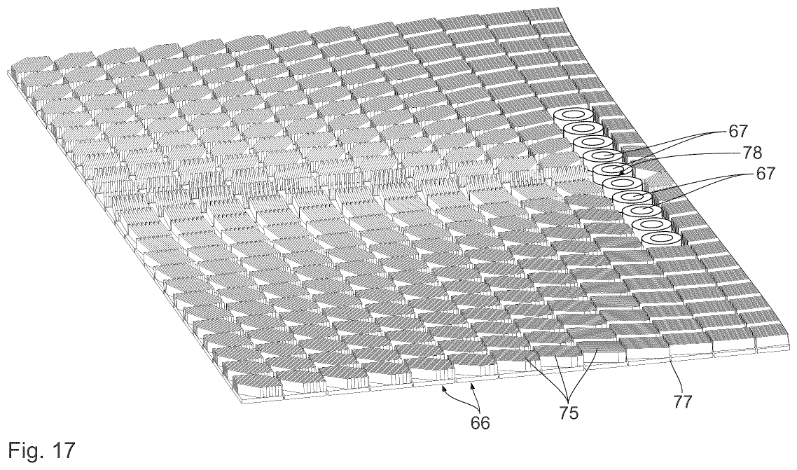

FIG. 5 schematically illustrates the arrangement of the decoupling apparatus 61 between the support structure 60 and the MEMS stack 54 with the mirror array 19, the front-end ASICs 51 and the controller ASICs 52. Other partial views of this arrangement are depicted in FIGS. 16 and 17.

According to the variant depicted in FIG. 5, a respective front-end ASIC 51 is provided for the control of 3×3 individual mirrors 20.

According to the variant depicted in FIG. 5, 4×4 front-end ASICs 51 are in each case arranged on one controller ASIC 52.

Alternative assignments of the front-end ASICs 51 to the individual mirrors 20 and/or to the controller ASICs 52 are also possible.

FIG. 5 schematically illustrates the bonding pads 53 of the front-end ASICs 51 and of the controller ASICs 52 of the decoupling apparatus 61.

The decoupling apparatus 61 extends in a main plane of extent that is oriented at right angles to the surface normal 36. The main plane of extent of the decoupling apparatus 61 forms a reference plane for positioning the individual mirrors 20. The surface normal 36 is also referred to as the vertical direction.

The decoupling apparatus 61 comprises a planar substrate, which is also referred to simply as plate 62 hereinbelow. One or more layers 63 with electrical connections can be provided on the substrate 62 and/or integrated into the latter. In general, the decoupling apparatus 61 may have electrical connections. The electrical connections, for example the layers 63, may be arranged in one or more planes that are parallel to the main plane of extent, which is to say perpendicular to the surface normal 36.

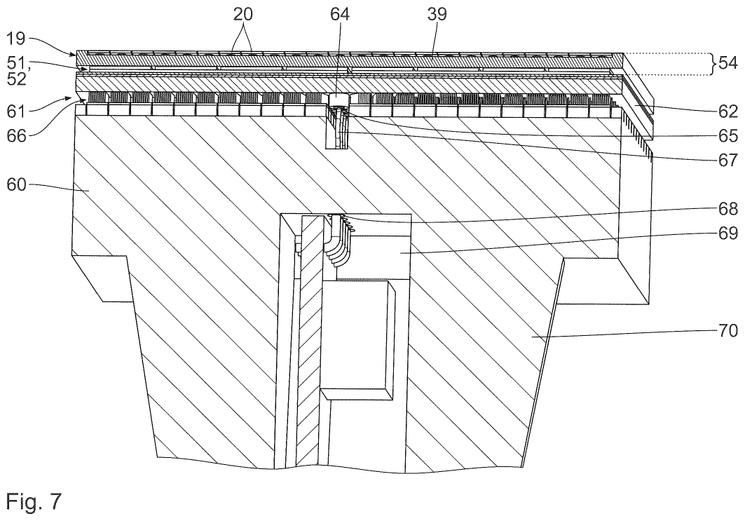

The decoupling apparatus 61 may also have TSVs 64. The TSVs 64 may have pads 65 (see FIG. 7), for example at their end distant from the mirror array 19.

For example, the TSVs 64 may serve for electrical contacting of the layers 63.

The decoupling apparatus 61 comprises a multiplicity of compensation elements 66 for compensating mechanical stresses. The compensation elements 66 will still be described in detail hereinafter.

The decoupling apparatus 61 is arranged on the support structure 60. For example, it is fixedly connected to the support structure 60. For example, the decoupling apparatus 61 can be bonded to the support structure 60.

The decoupling apparatus 61, for example the plate 62, may be produced from, for example consist of, a semiconductor material, for example silicon, or a semiconductor compound, for example a silicon compound.

For example, the support structure 60 is metallic. For example, it may be made of metal or comprise metallic regions. For example, it may have regions with high electrical and/or thermal conductivity. For example, it may be made of copper or comprise copper regions.

As illustrated in FIG. 7 in exemplary fashion, the pads 65 of the decoupling apparatus 61, for example of its TSVs 64, may be electrically connected to the layers 63. Via the layers 63, supply voltages and/or control signals can be guided to the controller ASICs 52 via the bonding pads 53. In this case, it can be desirable to keep the number of pads 65 and the vacuum bushings used to this end as low as possible. For example, the division of the electrical signals among a plurality of the controller ASICs 52 can be undertaken only in the layers 63 of the decoupling apparatus 61.

Contact pins 67 can be used to contact the pads 65 from the underlying region, for example from the support structure 60, the pads being provided for example in a non-vacuum region, for example a normal pressure region. The contact pins 67 can have an elastic embodiment in the axial direction. This makes it possible to establish a largely constant contact pressure and hence a reliable electrical connection by pressing against the pads 65 of the decoupling apparatus 61.

The contact pins 67 may also have a laterally resilient embodiment. This can be achieved by virtue of these being mechanically held at a certain distance from the pad 65 and the exposed part of the contact pins 67 having a small diameter. What can be achieved thereby is that the pads 65 of the decoupling apparatus 61, for example of the TSVs 64, need not have a flexible embodiment themselves. The pads 65 may be connected, for example securely connected, to the substrate 62 of the decoupling apparatus 61.

In this case, too, the lateral resilience of the contact pins 67 ensures the lateral compensation of the thermal expansion.

The fact that the TSVs 64 need not have any lateral resilience allows these to be formed with large cross sections. By way of example, the cross section of the TSVs 64 may be at least four times, for example at least 10 times and for example at least 20 times as large as the cross section of the contact pins 67, for example at the free end of the latter that comes into contact with the pad 65. A large cross section of the TSVs 64 is desirable from a manufacturing point of view. Additionally, this allows a very low resistance transmission of electrical signals.

For example, the contact pins 67 may be arranged in the support structure 60 via vacuum bushings 68.

During its ultimate use, for example in a projection exposure apparatus 1, for example in the illumination optical unit 4 of the projection exposure apparatus 1, the decoupling apparatus 61 may be arranged in the vacuum region, for example within the evacuable chamber 21.

The end of the support structure 60 distant from the individual mirrors 20 may be arranged in a normal pressure region. What are known as buffer electronics 69 may also be arranged in the normal pressure region, for example under atmospheric conditions. The buffer electronics 69 may serve to buffer and filter the supply voltages, for the driver stages for the outgoing signals and for the receiver stages for the incoming signals.

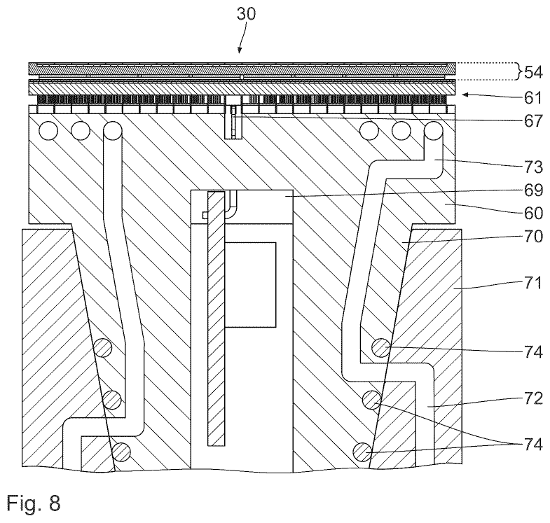

At its end distant from the mirror array 19, the support structure 60 may taper, for example be formed in conical or pyramidal fashion. For example, it may comprise a ferrule 70 for arranging the support structure 60 in a support frame 71 (see FIG. 8).

Fluid channels 72, which are depicted schematically in FIG. 8 and through which a cooling fluid may flow, can be arranged in the support frame 71. For example, a cooling fluid can be guided into corresponding fluid channels 72 in the support structure 60 via the fluid channels 72 in the support frame 71. The fluid channels 72 in the support structure 60 form cooling channels 73 for example. The support structure 60 can be cooled efficiently and reliably with the aid of the cooling channels 73.

The cooling channels 73 may be guided through the support structure in spiralling or meandering fashion.

O-rings 74 may be provided to seal the support structure 60 in the support frame 71.

The compensation elements 66 are described in detail hereinafter.

The compensation elements 66 each comprise a plurality of connecting elements 75. The connecting elements 75 are connected to the plate 62. For example, they may be formed in one piece with the plate 62.

The connecting elements 75 may be pin-shaped or planar. For example, they may be in the form of leaf springs. In general, they may be designed in the style of leaf springs, which is to say with a high mechanical stiffness in the vertical direction and a lower mechanical stiffness in at least one lateral direction. In this case, they may have a flat or curved embodiment.

The connecting elements 75 are also referred to as the legs of the decoupling apparatus 61. On account of their lateral resilience, they allow compensation of the different lateral thermal expansions at the transition from the support structure 60 to the decoupling apparatus 61, for example at the transition from metal to silicon.

However, on account of their relatively high vertical stiffness, they simultaneously ensure the stability of the orientation of the plate 62, which serves as a reference surface for the displacement position of the individual mirrors 20 of the mirror array 19.

The connecting elements 75 allow a compensation of different thermal expansions of the support structure 20 and the decoupling apparatus 61 at their joining points. For example, they enable a significant reduction in the deformative and/or destructive mechanical stress occurring at these positions.

According to the disclosure, provision is made for the connecting elements 75 to be produced via MEMS technology. This allows a very finely structured production of the connecting elements 75. This leads to the height of the connecting elements 75, which is to say their length in the direction of the surface normal 36, being very small. For example, they may have a height of less than 3 mm, such as a height in the range of 0.2 mm to 2 mm, and for example no more than 1 mm. These specifications should be understood to be exemplary.

A low height is desirable to obtain a small thermal resistance. At the same time, this yields the feature that inhomogeneous heat influxes into the mirror arrays 19 and/or into the decoupling apparatus 61 and the arising temperature gradients as a result of the low coefficient of thermal expansion of silicon lead only to small different thermal longitudinal expansions of the connecting elements. This reduces the local inclination errors which are caused by the longitudinal expansion of the connecting elements 75. Further provision is made for the connecting elements 75 to be used group-by-group in each case with a base element 76 which is also referred to as a foot. The base element 76 may have a planar embodiment. For example, it may have a planar structure 81 or be in the form of a planar structure 81. It may also have a plurality of planar regions. The connecting elements 75 may be formed in one piece, for example group-by-group, with a base element 76.

The base element 76 may form the respective contact region between the decoupling apparatus 61 and the support structure 60.

In addition to the contact region of the base element 76 with the support structure 60, stress decoupling cuts 77 can be provided in the support structure 60.

The stress decoupling cuts 77 may each be provided adjacent to a base element 76 and/or in a manner circumferentially around a base element 76.

For example, provision can be made for a, for example at least one, stress decoupling cut 77 to be arranged between two respective base elements 76 in the support structure 60.

The number and/or arrangements of the decoupling cuts 77 can for example correspond to the gaps between the individual mirrors 20 of the mirror array 19 or be matched thereto.

The functional principle of the connecting elements 75 is explained hereinafter with reference to FIGS. 6A and 6B.

FIG. 6A illustrates a stress-free initial situation by way of example. The connecting elements 75 are not deformed. For example, they extend parallel to the surface normal 36. Alternative directions of the connecting elements 75, for example an embodiment at an angle to the surface normal 36 and/or a curved embodiment, are also possible.

FIG. 6B illustrates the situation which arises when the support structure and the decoupling apparatus 61 heat up. The metallic support structure 60 expands to a greater extent than the decoupling apparatus 61 on account of the higher coefficient of thermal expansion. The difference in the lateral expansion between the plate 62 of the decoupling apparatus 61 and the support structure 60 is compensated by the lateral resilience of the connecting elements 75. This drastically reduces the thermomechanical stress introduced into the plate 62. Local stress remains between the base elements 76 and the support structure 60. This is depicted schematically by graph XII below FIG. 6B. This stress is restricted to the joining points between one of the base elements 76 and the support structure 60. The stress decoupling cuts 77 prevent the local stress regions in the region of the base elements 76 from combining to form a quasi-continuous shear stress along the surface of the support structure 60. This prevents a deformation of the support structure 60.

The shear stress and/or the peel stress, for example, can be interrupted and kept local via the stress decoupling cuts 77.

In each case combining a plurality of the connecting elements 75 to form a group which is connected to, or formed in one piece with, a common base element 76 causes each of these groups to independently form a parallel guide along the resilient direction of the connecting elements 75. This significantly reduces the influx of bending moments in the joining points.

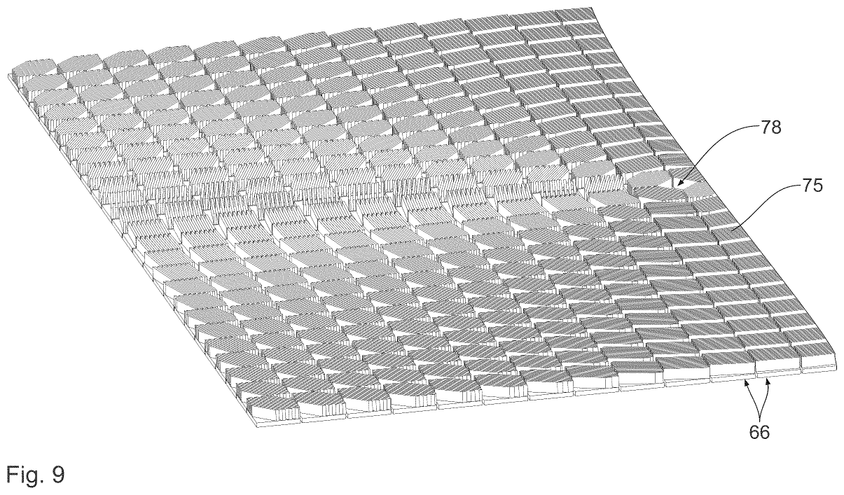

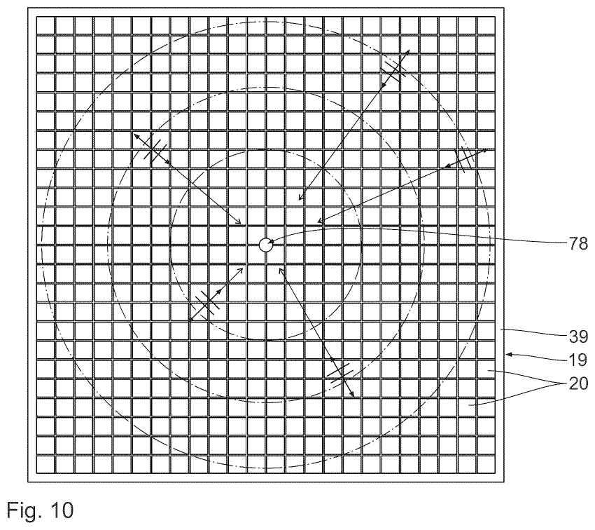

As depicted schematically in FIG. 10 and by way of example in FIG. 9, the connecting elements 75 can each be arranged in such a way that their resilient directions are arranged radially with respect to a centre 78 of the thermal expansion. For example, the centre 78 can be the geometric centre of one of the mirror arrays 19.

An isotropic thermal expansion in relation to this centre with very little thermal warpage is made possible as a result of an arrangement of the connecting elements 75 so as to be aligned with a common centre of the thermal expansion. The warpage is determined substantially exclusively by the low stiffness of the connecting elements 75 along the radial direction and the relative thermal expansion.

As depicted by way of example in FIG. 9, the connecting elements 75 can each be aligned, group-by-group, in parallel or concentric fashion.

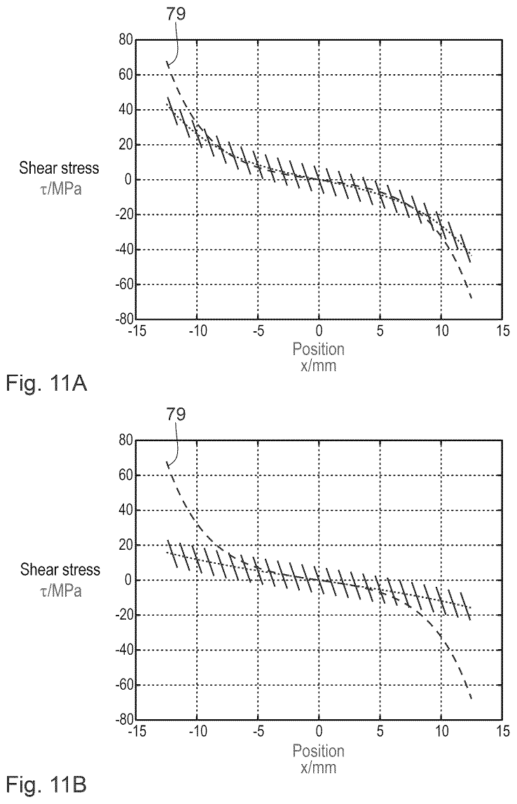

FIGS. 11A to D illustrate, by way of example and for different aspect ratios (height to thickness) of the connecting elements 75, the shear stress at the joining point between the decoupling apparatus 61 and the support structure 60 in the case of a homogeneous temperature increase of 100 K for the case where the support structure is made of copper and compensation elements 66 are made of silicon. The aspect ratio respectively is as follows: FIG. 11A: 5:1, FIG. 11B: 10:1, FIG. 11C: 15:1 and FIG. 11D: 20:1. The stress curves for the peel stress are similar to the shear stress depicted in exemplary fashion.

For comparison purposes, the figures moreover each illustrate a comparison curve 79 for the case of direct bonding between a silicon substrate and a copper substrate. The solid lines show the shear stress at the joining point; the dotted line shows the stress on the silicon substrate 62.

As indicated by the comparison curve 79, heating by 100 K would lead to a shear stress of more than 150 MPa. This is significantly above the stress limit for bonding points.

The short lines, which show the stress curve in question at the bonding points, indicate that the shear stress is reduced by a factor of more than 3, at least above an aspect ratio of 10:1. The maximum shear stress in the plate 62 has been reduced by a factor of more than 4 in the case of an aspect ratio of at least 10:1.

The global shear stress can be reduced further as the aspect ratio of the connecting elements 75 increases.

As is qualitatively evident from FIGS. 11A to D, the stress in the bonding points dominates at an aspect ratio of 20:1. A further reduction in the global stress curve would, in general, only be advantageous if the stress level arriving at the substrate 62 would have to be reduced even further.

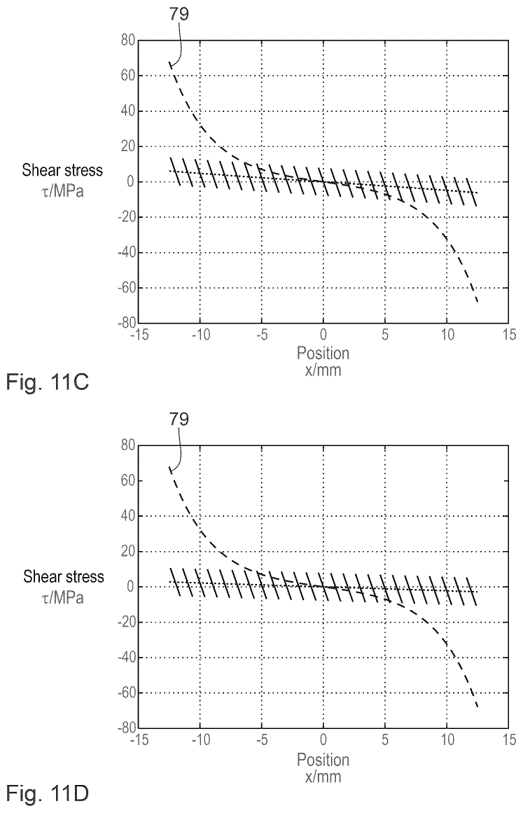

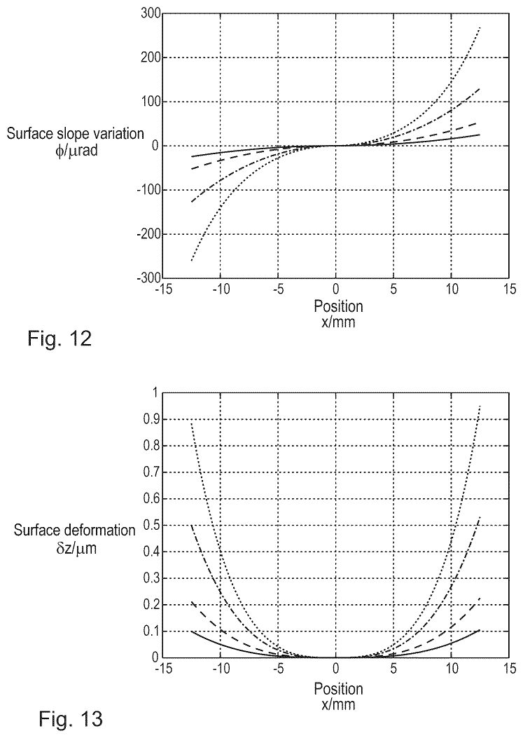

FIGS. 12 and 13 show an estimate for the deformation of the plate 62 for the stress curves shown in FIGS. 11A to D. As is qualitatively evident, the deformation of the carrier plate 62 reduces significantly as the aspect ratio increases, which is to say as the shearing stress reduces.

In this case, FIG. 12 shows, by way of example, the surface slope variation @ of a 10 mm thick plate 62 when the same heats up from 20° C. to 120° C.

FIG. 13 shows, by way of example, the surface deformation δz along the surface normal.

Both figures in each case show different curves for the different aspect ratios (height: thickness) of the connecting elements 75, which form the basis for FIGS. 11A to D.

The connecting elements 75 increase the thermal resistance between the plate 62 of the decoupling apparatus 61 and the support structure 60. However, it has been possible to show that this increase can be kept sufficiently small. To this end, a large area fill factor of the connecting elements 75, for example, is desirable. It has been possible to show that the thermal resistance was increased by less than a factor of 10, such as by less than a factor of 5, and for example by less than a factor of 3 as a result of the structured embodiment of the connecting elements 75.

A height of the connecting elements 75 of for example 500 μm would lead to an effective thickness of a thermally equivalent unstructured wafer of approximately 1250 μm. This would correspond to a thermal resistance of 16 mK/W in the case of an assumed footprint of the MEMS unit of 25 mm×25 mm. This is approximately one order of magnitude less than the thermal resistance obtained on the same area by a polymer adhesive with a thickness of 100 μm for example.

The decoupling apparatus 61 can be produced via MEMS technology.

For example, it is possible to implement the structuring of the connecting elements 75 and of the base elements 76, which for example may be formed in one piece with the plate 62, via MEMS technology.

Even though the disclosure was presently described in relation to a mirror array for a projection exposure apparatus 1, for example in the illumination optical unit 4 of the projection exposure apparatus 1, the application of the disclosure is not limited to this special case.

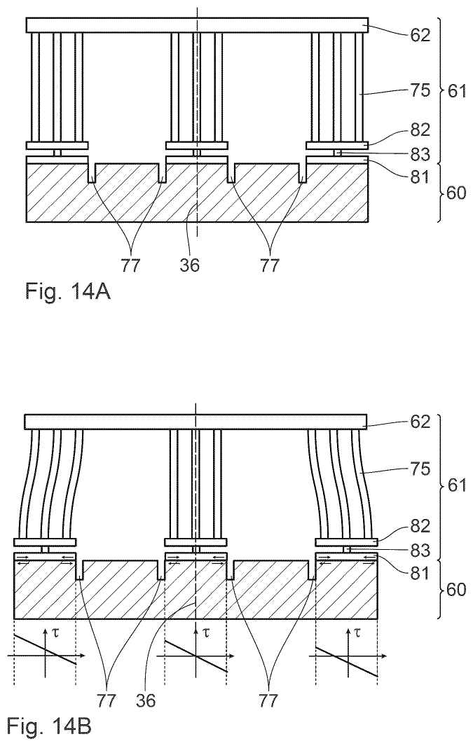

FIGS. 14A and 14B schematically describe a variant of the decoupling apparatus 61. In part, the decoupling apparatus 61 corresponds to the decoupling apparatus 61 according to FIGS. 6A and 6B, the description of which is referred to herewith.

Unlike the variant according to FIGS. 6A and 6B, the base element 76 of this variant has two planar structures 81, 82. The planar structures 81, 82 are connected to one another by way of a joint, which is in the form of a tilting joint 83 for example.

The joint allows pivoting of the planar structures 81, 82 with respect to one another. For example, it enables moment decoupling.

The joint may have one or more, for example defined, degrees of tilt freedom. It may have an isotropic tilting stiffness. It may also be softer or stiffer in some directions compared to other directions.

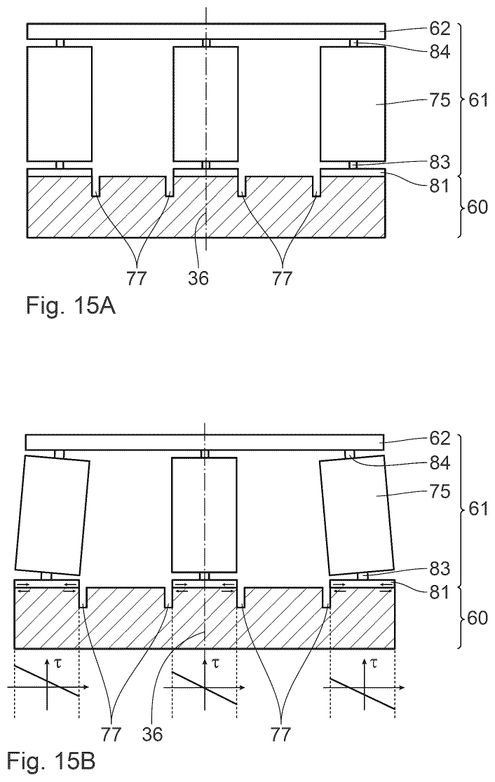

FIGS. 15A and 15B schematically describe a further variant of the decoupling apparatus 61. In part, the decoupling apparatus 61 corresponds to the decoupling apparatus 61 according to FIGS. 6A and 6B, the description of which is referred to herewith.

Unlike the variant according to FIGS. 6A and 6B, the decoupling apparatus 61 in each case has a decoupling element. At a first end, the decoupling element is pivotably connected to the plate 62 by way of a joint, which is in the form of a tilting joint 84 for example.

For details of the joint, reference is made to the description hereinbefore.

At a second end, the decoupling element is pivotably connected to the planar structure 81 of the base element 76 by way of a joint, which is in the form of a tilting joint 83 for example.

The decoupling element has a central thickening. The depicted cross section of the decoupling element should be understood to be exemplary. Other cross sections are possible.

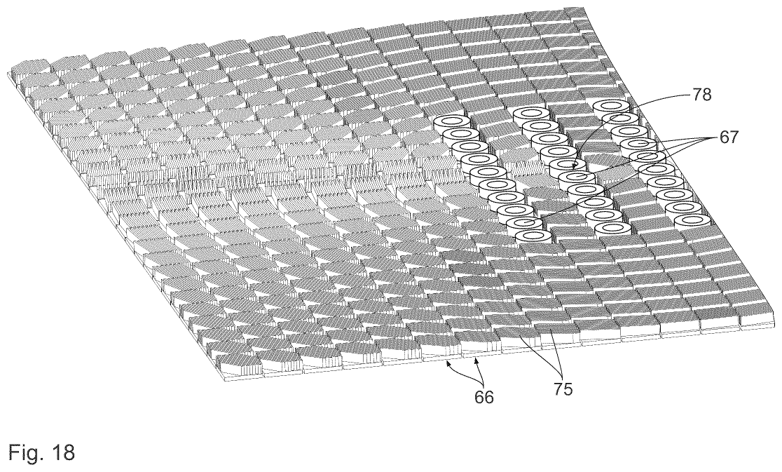

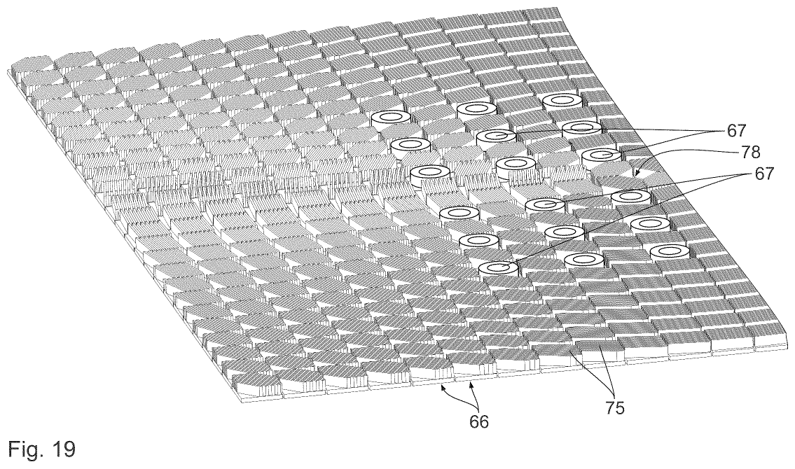

By way of example, FIG. 18 illustrates a variant for arranging the contact pins 67 in accordance with FIG. 17. In this variant, the contact pins 67 are arranged in three rows. Ten contact pins 67 are arranged in each row. Other numbers of rows and/or numbers of contact pins 67 per row are possible.

By way of example, FIG. 18 illustrates a variant for arranging the contact pins 67 in accordance with FIG. 17. In this variant, the contact pins 67 are arranged around the centre of the plate 61 in a pattern of 2×2 blocks, each with 3×3 contact pins 67.

The blocks are also referred to as contact fields or contacting fields.

In the variant depicted in FIG. 18, the pins are arranged in open two-dimensional contact fields, in which the individual contact fields are surrounded by fields with connecting elements and hence the lengths to be bridged are kept as short as possible in both lateral directions.

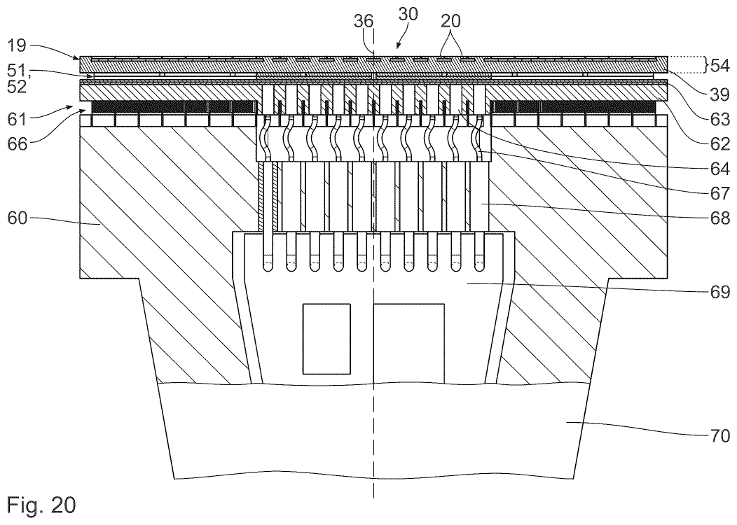

By way of example, FIG. 20 illustrates a variant of an arrangement in accordance with FIG. 5. The arrangement largely corresponds to the arrangement according to FIG. 5, the description of which is referred to hereby. In the variant depicted in FIG. 20, the contact pins 67 have a laterally resilient design. They may bend, especially when pressed against the pads 65 (see FIG. 7).

The different aspects of details described hereinbefore on the basis of individual figures can substantially be combined freely with one another.

What is claimed is:

1. An apparatus, comprising:
a plate extending in a main plane of extent; and
a plurality of connecting elements extending across the main plane of extent; and
a plurality of base elements,
wherein:
each base element has a plurality of connecting elements connected thereto;
the connecting elements have a greater stiffness in a direction perpendicular to the main plane of extent than in at least one direction perpendicular to the main plane of extent;
the apparatus is a MEMS apparatus; and
the apparatus is configured to mount MEMS-based micromirrors on a metallic support structure.

2. The apparatus of claim 1, wherein 50% of the apparatus comprises silicon or a silicon compound.

3. The apparatus of claim 1, wherein 50% of the apparatus consists of silicon or a silicon compound.

4. The apparatus of claim 1, wherein the connecting elements are at most three millimeters long in a direction perpendicular to the main plane of extent.

5. The apparatus of claim 4, wherein the connecting elements have an effective thickness of at most 300 micrometers in a direction perpendicular to the main plane of extent.

6. The apparatus of claim 1, wherein the connecting elements have an effective thickness of at most 300 micrometers in a direction perpendicular to the main plane of extent.

7. The apparatus of claim 1, wherein:
the connecting elements comprise leaf springs arranged in groups; and
for each group of leaf springs, the leaf springs in the group are parallel to each other.

8. The apparatus of claim 1, wherein the base elements comprise a planar structure connected to a joint.

9. The apparatus of claim 1, wherein the plate comprises through silicon vias or copper vias in silicon configured to transmit control signals and/or supply voltages.

10. The apparatus of claim 1, wherein the plate comprises an electrically conductive layer, a conductor track, a passive component, and/or an active component.

11. The apparatus of claim 1, wherein the connecting elements comprise MEMS-based connecting elements.

12. The apparatus of claim 11, wherein the connecting elements are at most three millimeters long in a direction perpendicular to the main plane of extent.

13. The apparatus of claim 11, wherein the connecting elements have an effective thickness of at most 300 micrometers in a direction perpendicular to the main plane of extent.

14. An optical component, comprising:
a micromirror array comprising a plurality of MEMS-based micromirrors; and
an apparatus according to claim 1.

15. The optical component of claim 14, further comprising interposed layers of ASIC chips connecting the micromirror array and the apparatus via bonding structures.

16. An optical assembly, comprising:
a support structure configured to hold optical components;
an apparatus according claim 1; and
a micromirror array comprising a plurality of MEMS-based micromirrors,
wherein the micromirrors are supported on the support structure by the apparatus.

17. The optical assembly of claim 16, further comprising bonding structures that directly or indirectly connect the base elements of the apparatus to the support structure.

18. The optical assembly of claim 16, the support structure comprises vacuum bushings configured to lad contact elements through in vacuum-tight fashion to electrically contact the apparatus.

19. The optical assembly of claim 16, wherein elastically or resiliently designed and/or elastically mounted contact elements are arranged at least in certain regions in the support structure for the purpose of contacting the apparatus.

20. A microlithographic projection exposure apparatus, comprising:
an illumination optical unit configured to illuminate a portion of an object in an object field of an object plane; and
a projection optical unit configured to image the illuminated portion of the object into an image field of the projection optical unit,
wherein the illumination optical unit comprises:
an optical assembly, comprising:
a support structure configured to hold optical components;
an apparatus according claim 1; and
a micromirror array comprising a plurality of MEMS-based micromirrors, and
wherein the micromirrors are supported on the support structure by the apparatus.
